(19) United States
(12) Patent Application Publication
(10) Pub. No.: US 2017/0237923 A1
(43) Pub. Date: Aug. 17, 2017

(54) SELECTIVELY ATTENUATING LIGHT ENTERING AN IMAGE SENSOR

(71) Applicant: Cisco Technology, Inc., San Jose, CA (US)

(72) Inventor: Farhad Abbassi GHOLMANSARAEI, Danville, CA (US)

(21) Appl. No.: 15/041,256

(22) Filed: Feb. 11, 2016

(51) Int. Cl. H04N 5/378; G03B 9/08; G02F 1/1335; G02F 1/1337; H04N 5/353; H01L 27/146

(52) U.S. Cl. CPC H04N 5/378; H04N 5/3532; H01L 27/1462; H01L 27/14627; H01L 27/14645; G02F 1/133528; G02F 1/133711; G03B 9/08; G02F 2001/133726

(57) ABSTRACT

A double-sided image sensor can capture images from two different perspectives during two different time intervals. For example, during a first time period, the image sensor captures the view relative to a first side of an electronic device containing the image sensor, but during a second time period, captures the view relative to a second side of the electronic device. To capture images from multiple views, the double-sided image sensor contains a layer of photodiodes which captures measurements from multiple directions. Moreover, the image sensor includes selectable attenuators (e.g., mechanical shutters or TN attenuators) which control what view the photodiodes are currently capturing. For example, when capturing an image from the backside of the electronic device, one of the selectable attenuators blocks light from striking the photodiodes from the front side, and as such, only the light entering at the backside strikes the photodiodes.

### TECHNICAL FIELD

Embodiments presented in this disclosure generally relate to a double-sided image sensor.

### BACKGROUND

Many electronic devices include front-facing and rear-facing cameras that capture images on opposite sides of the device. For example, the front-facing camera may be used to capture images of the user who is holding the device while the rear-facing camera captures images of the environment the user is facing. However, such an arrangement requires the electronic device to include separate image sensors for both cameras which increases the cost of the electronic device. Moreover, the two cameras may also have respective read out circuitry for processing and generating images using the measurements captured by the image sensors. As such, integrating multiple cameras into the electronic device can increase its cost and complexity.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a block diagram of a double-sided image sensor, according to one embodiment presented herein.

FIG. 2 is a block diagram of a double-sided image sensor with mechanical shutters, according to one embodiment presented herein.

FIG. 3 is a block diagram of a double-sided image sensor with twisted nematic attenuators, according to one embodiment presented herein.

FIG. 4 illustrates a twisted nematic attenuator, according to one embodiment described herein.

FIG. 5 illustrates an electronic device containing a double-sided image sensor, according to one embodiment described herein.

FIGS. 6A-6B illustrate different twisted nematic attenuators, according to one embodiment described herein.

FIG. 7 is a flowchart for increasing the dynamic range of an image sensor using an individually addressable twisted nematic attenuator, according to one embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DESCRIPTION OF EXAMPLE EMBODIMENTS

### Overview

One embodiment presented in this disclosure is an image sensor that includes a first selectable attenuator, a second selectable attenuator, and a photodiode layer disposed optically between the first and second selectable attenuators. Moreover, the photodiode layer includes an array of photodiodes. The image sensor also includes a controller configured to control attenuation factors of the first and second selectable attenuators during a first time period to capture a first image relative to a first side of the array of the photodiodes and control the attenuation factors of the first and second selectable attenuators during a second time period to capture a second image relative to a second side different from the first side of the array of the photodiodes.

Another embodiment presented in this disclosure is a method. The method includes controlling a first attenuation factor of first selectable attenuator in an image sensor during a first time period to capture a first image relative to a first side of an array of photodiodes and controlling an second attenuation factor of a second selectable attenuator in the image sensor during the first time period to substantially block incident light from striking a second side of the array of photodiodes. The method includes controlling the first attenuation factor the first selectable attenuator during a second time period to substantially block incident light from striking the first side and controlling the second attenuation factor of the second selectable attenuator during the second time period to capture a second image relative to the second side of the array of photodiodes.

Another embodiment presented in this disclosure is an image sensor that includes photodiodes disposed in an array, a TN attenuator layer comprising a plurality of individually addressable TN attenuators disposed over respective ones of the photodiodes, and a controller. The controller is configured to receive an intensity measurement for a first photodiode in the array of photodiodes and, upon determining the first photodiode is saturated based on the intensity measurement, adjust a gain of a first TN attenuator of the TN attenuators corresponding to the first photodiode thereby reducing the amount of light striking the first photodiode. The controller is configured to generate an image using measurements received from the photodiodes.

### EXAMPLE EMBODIMENTS

Embodiments herein describe a double-sided image sensor that can capture images from two different perspectives during two different time periods. For example, during a first time period, the image sensor captures the view relative to a first side of an electronic device containing the image sensor, but during a second time period, captures the view relative to a second side of the electronic device. In one embodiment, the first and second sides are opposing sides in the electronic device—e.g., a front side and backside.

To capture images from multiple views, the double-sided image sensor contains a layer of photodiodes which captures measurements from multiple directions. For example, the photodiodes may detect incident light that strikes the layer on the backside and the front side of the layer. In this manner, the photodiodes can capture images from either the front side or the backside perspectives of the electronic device. Moreover, the image sensor includes selectable attenuators (e.g., mechanical shutters or twisted nematic (TN) attenuators) which control what view the photodiodes are currently capturing. In one embodiment, the selectable attenuators permit the photodiodes to capture light only from one view at a time. For example, when capturing an image from the backside of the electronic device, a first selectable attenuator blocks light from striking the photodiodes from the front side. As such, the only light striking the photodiodes in the light entering at the backside of the electronic device. Conversely, when capturing an image from the front side of the electronic device, a second selectable actuator blocks light from striking the photodiodes from the backside, so the only light measured by the photodiodes is the light entering at the front side of the electronic device.

In one embodiment, an addressable TN attenuator can be used to increase the dynamic range of the image sensor. The addressable TN attenuator includes a plurality of individual TN attenuators that can be controlled or addressed separately. By measuring the intensity of the light at each pixel in the image sensor, the electronic device can detect pixels that are saturated (i.e., when the captured light exceeds the dynamic range of the read out circuitry). The electronic device instructs the individual TN attenuators corresponding to the saturated pixels to attenuate the light (e.g., reduce the light by 50%, 75%, 90%, etc.) such that the light measured by the image sensor is now within the dynamic range of the read out circuitry. Since the amount of attenuation is known, the electronic device can adjust the measurement outputted by the read out circuitry to identify the true intensity corresponding to the pixel—i.e., the measurement that would have been measured if the read out circuitry had infinite range. Using an addressable TN attenuator to increase the range on the image sensor can be used in either double-side image sensors or single-side image sensors.

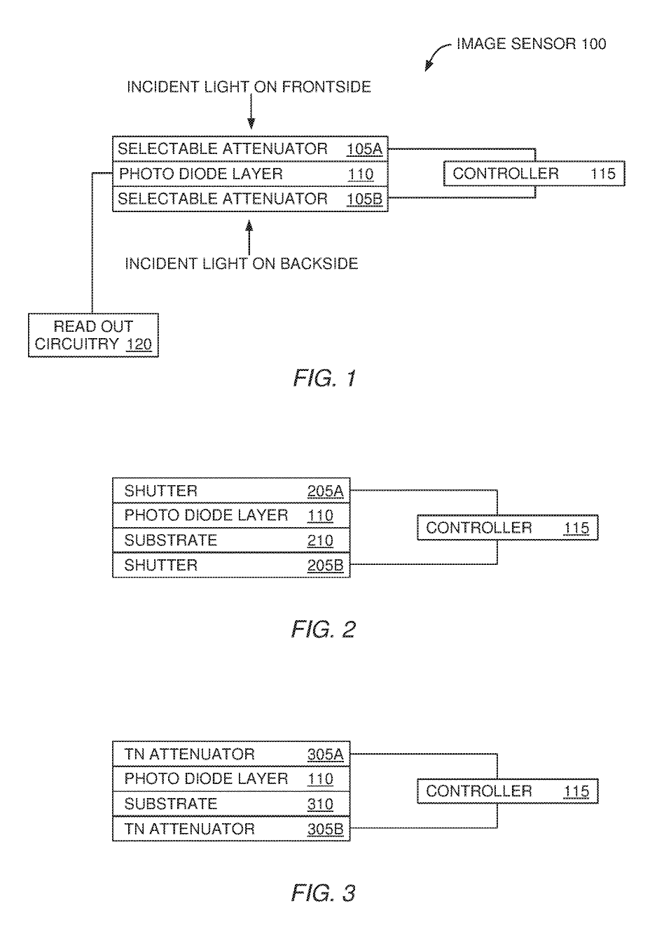

FIG. 1 is a block diagram of a double-sided image sensor 100, according to one embodiment presented herein. The image sensor 100 includes selectable attenuators 105 disposed on either side of a photodiode layer 110—e.g., a CMOS sensor. In this example, incident light strikes a front side and a backside of the image sensor. Before reaching the photodiode layer 110, the incident light passes through one of the selectable attenuators 105. Moreover, the photodiode layer 110 includes individual photodiodes that are arranged in an array along a common plane. In this embodiment, the photodiodes are capable of measuring incident light striking the sensor 100 on both the front side and the backside. That is, the same photodiodes used to measure light entering from the front side of the image sensor 100 are also used to measure light entering at the backside of the sensor 100. Thus, instead of having two photodiode layers (e.g., two separate image sensors), only one layer of photodiodes are used to captures images in two different directions—i.e., the front side and backside.

FIG. 1 is a top view of the image sensor where the attenuators 105 cover the front side and backside of the photodiode layer 110. For example, the selectable attenuators 105 cover the front side and backside of the photodiode layer 110 such that the incident light passes through the attenuators 105 before reaching the photodiodes in layer 110. A controller 115 determines which image the photodiode layer 110 is currently capturing. To do so, the controller 115 includes hardware, software, firmware or combinations thereof to perform the functions herein. For example, to capture a front side image, the controller 115 sends control signals that permit the light arriving at the front side of the sensor 100 to pass substantially unabated through attenuator 105A (a low attenuation factor) while the light arriving at the backside of the sensor 100 is substantially attenuated or blocked by the attenuator 105B (a high attenuation factor). As used herein, “substantially unabated” means the attenuator 105A is configured in a first mode to permit light to pass through although some light may be filtered out by the material of the attenuator 105. Conversely, “substantially block” means the attenuator 105B is configured in a second mode to block light from passing through. However, even when substantially blocking light, the attenuator 105B may permit some light to pass through—i.e., the attenuator 105B may not be capable of blocking 100% of the incident light. The controller 115 provides signals that control the modes of the attenuators 105. Conversely, even when permitting the light to pass substantially unabated, the attenuators 105 may block some of the light passing through them.

In one embodiment, the controller 115 ensures that one attenuator 105 is always configured in the second mode with a high attenuation factor to block light entering from one side of the image sensor 100. In this manner, the photodiodes in layer 110 measure incident from only direction at a time.

The image sensor 100 includes read out circuitry 120 that receives the output signals generated by the photodiodes in layer 110. The read out circuitry 120 generates images corresponding to the measured data by, for example, using an analog to digital converter to convert the analog values provided by the photodiodes into digital values that each correspond to a pixel in a digital image. Put differently, the read out circuitry 120 includes hardware that uses the measurements captured by the photodiodes in layer 110 to generate digital images that can be displayed or stored.

Moreover, although FIG. 1 illustrates the photodiode layer 110 capturing images in two parallel directions—e.g., the front side and backside—the embodiments herein are not limited to such. For example, the image sensor may include one or more mirrors or lens that permit the photodiodes to capture images from non-parallel views. For example, instead of capturing views of the front and backsides, the image sensor 100 may capture views of the front and top sides of the electronic device. For example, the sensor 100 may include beam steering and/or focusing elements that reflect light entering the sensor 100 from the top side (i.e., the direction into the page) at a forty five degree angle relative to the top side such that it strikes the photodiode layer 110 in the same direction as the light incident from the backside of the sensor 100 as shown here. In this example, the attenuator 105B could be located at the same location as shown in FIG. 1 (e.g., between the photodiode layer 110 and the mirror reflecting the light) or could be located at the top image sensor 100 to selectively block the light before the light reaches the reflective mirror. In this manner, the image sensor 100 can include any number of optical components for permitting the image sensor 100 to capture two different views using the same photodiode layer 110.

FIG. 2 is a block diagram of a double-sided image sensor 200 with mechanical shutters 205, according to one embodiment presented herein. That is, in this example the selectable attenuators 105 shown in FIG. 1 are mechanical shutters 205 which are activated and deactivated by the controller 115. For example, when capturing an image from the front side of the image sensor 200, shutter 205A is open (i.e., in a first mode with a low attenuation factor) thereby permitting light to strike the photodiode layer 110. However, the shutter 205B is closed (i.e., in a second mode with a high attenuation factor) thereby preventing the light incident on the backside of the sensor 200 from striking the photodiode layer 110. When taking an image from the perspective of the back of the image sensor 100, the controller 115 opens the shutter 205B but closes shutter 205A. In this manner, only light incident on the backside of the sensor 200 reaches the photodiode layer 110.

Moreover, the photodiode layer 110 is mounted on a substrate 210 which can be any material that is translucent. For example, the substrate 210 may be a plastic or glass that provides structural support to the photodiode layer 210 but permits light passing through the shutter 205B to reach the photodiode layer 110. In one embodiment, the photodiodes in the layer 110 are formed on, or applied to, the substrate 210.

FIG. 3 is a block diagram of a double-sided image sensor 300 with TN attenuators 305, according to one embodiment presented herein. Instead of mechanical actuators, image sensor 300 uses the twisted nematic affect to selectively block the light entering the front and backsides of the image sensor 300. As illustrated in more detail below, the twisted nematic effect can use polarizers and liquid crystal material to selectively block the light passing through the TN attenuators 305. In one embodiment, the controller 115 applies voltages to each of the attenuators 305 that determine if the attenuators 305 are in the first mode with a low attenuation factor and permit light to pass through substantially unabated, or in the second mode with a high attenuation factor and block the light from passing through. In this manner, the controller 115 configures the image sensor 300 to capture either a front side image or a backside image.

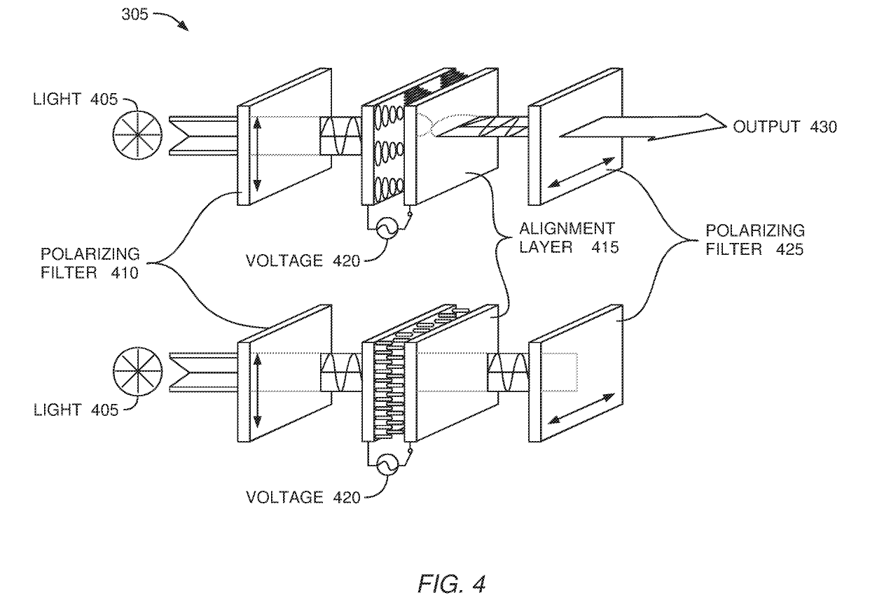

FIG. 4 illustrates a TN attenuator 305 shown in FIG. 3, according to one embodiment described herein. Specifically, FIG. 4 illustrates the TN attenuator 305 when configured in the first mode (which permits light to pass through) and the second mode (which blocks light from passing through). The upper image in FIG. 4 illustrates the TN attenuator 305 in the first mode while the lower image illustrates the attenuator 305 in the second mode.

The TN attenuator 305 includes a first polarizing filter 410, an alignment layer 415, and a second polarizing filter 425. As shown, incident light 405 strikes the polarizing filter 410 which permits only the light polarized in the vertical direction (as shown by the arrow in the filter 410) to pass through unabated. That is, the incident light 405 may include light polarized at multiple different angles. However, the polarizing filter 410 permits only light with a particular polarization—vertical polarization in this example—to pass through to the alignment layer 415.

The alignment layer 415 includes liquid crystal material whose properties are changed based on the voltage 420. For example, the alignment layer 415 may include two electrodes on opposite ends on which the voltage 420 is applied. In one embodiment, the voltage 420 may be generated by the controller 115 shown in FIGS. 1-3.

Changing the voltage 420 across the liquid crystal material changes the properties of the material. Specifically, the voltage 420 controls the alignment of liquid crystal molecules in the liquid crystal material, which controls the twisted nematic effect. For example, the first mode may be an OFF state when no electrical field is applied to the liquid crystal material. This mode is shown in the upper image where the alignment layer 415 rotates the polarized light exiting the polarizing filter 410 by ninety degrees. That is, the alignment layer 415 rotates the vertically polarized light to horizontally polarized light. Because the horizontal light matches the polarization direction of polarizing filter 425, the light passes through the filter 425. Stated differently, with only minor attenuation, in the first mode, the TN attenuator 305 permits the incident light 405 to pass through the polarizing filter 410, alignment layer 415, and polarizing filter 425. The output 430 of the TN attenuator 305 is then provided to the photodiode layer as shown in FIG. 3.

As shown in the lower image, in the second mode (e.g., an ON state), the voltage 420 changes the orientation of the liquid crystal molecules such that the TN attenuator 305 blocks incident light from passing through. Like in the upper image, the filter 410 permits only the vertically polarized incident light 405 to pass through. However, the voltage 420 across the alignment layer 415 causes the liquid crystals to shift (or break alignment) such that the liquid crystal does not re-orient the polarized light as shown in the upper image. As a result, the light exiting the alignment layer 415 has the same polarization as the light entering the alignment layer 415—e.g., a vertical polarization in this example. Thus, the vertically polarized light is blocked by the filter 425. Put differently, because the light has a different polarization than the polarization of the filter 425, filter 425 absorbs or reflects the light rather than permitting it to pass through. Thus, the TN attenuator 305 does not output light when in the second mode and no light is permitted to reach the photodiodes in the image sensor through the TN attenuator 305.

Having a respective TN attenuator 305 on each side of the photodiode layer permits the controller to allow light from only one side the photodiodes at any given time. For example, while one TN attenuator 305 is in the first mode as shown by the upper image in FIG. 4, the other TN attenuator 305 is in the second mode as shown by the lower image in FIG. 4. In this manner, the TN attenuator 305 can selectively switch which side of the image sensor is permitted to pass light to the photodiodes and which side is blocked.

In another embodiment, instead of using TN attenuators, the image sensor may use respective organic light emitting diodes (OLEDs) on either side of the photodiode layer as selectable attenuators. To block the light from striking one side of the photodiode layer, one of the OLEDs can emit light which is not detectable by the photodiodes in the photodiode layer (e.g., a first mode). When in this mode, the light emitted by the OLEDs strike the photodiode (which is not detected) while the light entering from the environment is blocked. Alternatively, to permit the light to strike the photodiode layer, the OLEDs are not driven (i.e., a second mode), and thus, are transparent so that light can pass through and strike the photodiode layer.

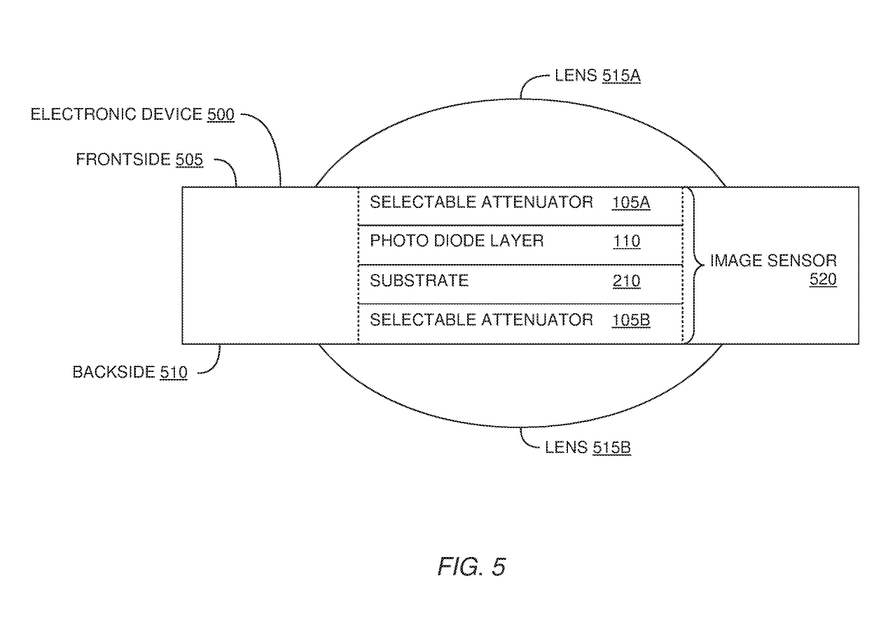

FIG. 5 illustrates an electronic device 500 containing a double-sided image sensor 520, according to one embodiment described herein. Specifically, FIG. 5 provides a top view of the electronic device 500 which may be a mobile phone, tablet computer, laptop, camera, a teleconference imager, and the like. The dotted portion illustrate where the top of the electronic device 500 has been removed so the details of the image sensor 520 inside the electronic device 500 can be seen. As shown, the image sensor 520 extends between a front side 505 and a backside 510 of the electronic device 500. Although not shown by the top view in FIG. 5, the selectable attenuators 105, the photodiode layer 110, and substrate 210 extend into the page to form a sensor stack. For example, the photodiode layer 110 may include an array of photodiodes arranged in rows in columns which is not shown in FIG. 5.

The electronic device 505 includes lenses 515 which focus light striking the front side 505 and backside 510 of the device 500. Specifically, lens 515A focuses the light striking the front side 505 of the electronic device 500 onto the front side of the array formed by the photodiodes in layer 110, while lens 515B focuses the light striking the backside 510 of the electronic device 500 onto the backside of the photodiode array in layer 110. That is, the photodiodes in layer 110 can sense light on at least two sides so that each of the photodiodes in the array can sense light incident on the front side 505 and backside 510 of the device 500. As described above, the controller (not shown) can selectively control the attenuators 105 such that light received on only one side of the electronic device 500 is able to strike the photodiodes in layer 110 at any given time.

In one embodiment, the device 505 may be used to capture images from the front side 505 and the backside 510 in quick succession. In one example, the image sensor 520 may capture a view relative to the front side 505 by permitting light to pass through attenuator 105A and block light using attenuator 105B. The image sensor 520 then closes attenuator 105A and opens attenuator 1056 to capture an image relative to the back side 510. If the image sensor 520 has a frame rate of 120 frames per second, the two images can be captured in 1/60th of a second. In one embodiment, the image of the front side 505 may include the user who is holding the device 505 while the image of the backside 510 captures the environment the user is viewing. An application can then fuse the two images into a single image so that the user and the environment she is viewing is in the same image.

In another embodiment, the device 505 may capture a plurality of images by alternating between the front side 505 and backside 510 views using the selectable attenuators 105. For example, to capture a 360 panoramic view, the device 505 can alternate between the front side 505 and backside 510 views to capture images on both sides of the device 505 as the user rotates the device 505 along an axis perpendicular to the ground. As a result, the panoramic view can be captured in half the time (i.e., the user only has to move the device 505 180 degrees rather than 360 degrees). In another example, the device 505 can simultaneously capture video from both sides of the device 505. For example, if the image sensor 520 captures images at 120 frames per second, the image sensor 520 can capture two videos (at a frame rate of 60 frames per second) that capture events occurring simultaneously at the front side 505 and backside 510.

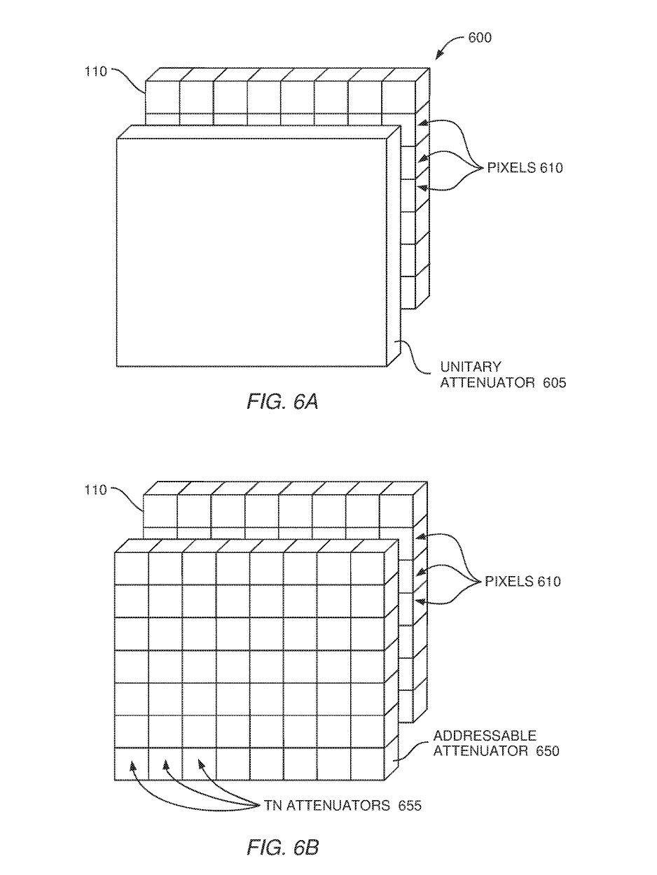

FIGS. 6A-6B illustrate different TN attenuators, according to one embodiment described herein. FIG. 6A illustrates an image sensor stack 600 that includes a photodiode layer 110 covered by a unitary TN attenuator 605. As shown, the photodiode layer 110 includes individual pixels 610 that each includes at least one photodiode for detecting incident light. As described above, the measurements captured by the photodiode or diodes in each of the pixels 610 can be transmitted to read out circuitry that generates a digital image with respective pixels from the measurements.

The pixels 610 in the photodiode layer 110 are covered by the unitary TN attenuator 605. That is, the TN attenuator 605 is disposed between the photodiode layer 110 and the light which is used to generate a captured image. Thus, the light passes through the TN attenuator 605 in order to reach the photodiode layer 110. By controlling the voltage across the TN attenuator 605, the electronic device can control how much of the light reaches the photodiode layer 110. For example, in the first mode, the TN attenuator 605 permits the light to pass through substantially unabated to reach the photodiode layer 110 as shown by the upper image in FIG. 4. However, in the second mode, the TN attenuator 605 blocks the light from reaching the photodiode layer 110 as shown by the lower image in FIG. 4.

FIG. 6B illustrates a TN attenuator layer 650 that includes individually controllable/addressable attenuators 655. That is, instead of a unitary TN attenuator 605 as shown in FIG. 6A where one voltage can be used to control the entire attenuator 605, here, the controller provides voltages for each of the individual TN attenuators 655 in the layer 650. In one embodiment, each one of the individual attenuators 655 corresponds to exactly one of the pixels 610 in the photodiode layer 110. For example, each of the TN attenuators 655 covers one of the pixels 610 in the layer 110. Because the attenuators 655 are individually controlled or addressable by separate control signals, the voltage across each of attenuators 655 can be set to different values. Thus, the voltage across one of the attenuators 655 can be set to block light while the voltage across another attenuator 655 can be set to permit light to pass through unabated to the underlying pixels 610.

In one embodiment, the voltages across the individual attenuators 655 are controlled to attenuate the light at predefined percentages. That is instead of only blocking the light or permitting the light to pass, the controller can apply intermediate voltages across the individual attenuators 655 to block a portion of the light. For example, a first voltage can block half the light (50% attenuation), a second voltage can block two thirds of the light (66% attenuation), and a third voltage can block three fourths of the light (75% attenuation). Of course, these attenuation settings are just examples. The controller may apply any number of voltages to achieve different attenuation levels of the light striking the photodiode layer 110.

One advantage of setting individual attenuation levels for each of the attenuators 655 is that doing so can improve the dynamic range of the image sensor. As will be described in more detail below, using the individual attenuators 655 to reduce the light entering specific pixels 610 can prevent the measurements generated by the pixels 610 from saturating the read out circuitry. Preventing the pixels 610 from saturating means the read out circuitry (or a software application) can correctly interpret the intensity of the light at the pixels 610.

Moreover, although FIGS. 6A and 6B, illustrate that the TN attenuators 605 and 650 and the photodiode layer 110 are square or rectangular, these components may be different shapes in other image sensors. For example, the attenuators 605 and 650 and the layer 110 may be circular or oval.

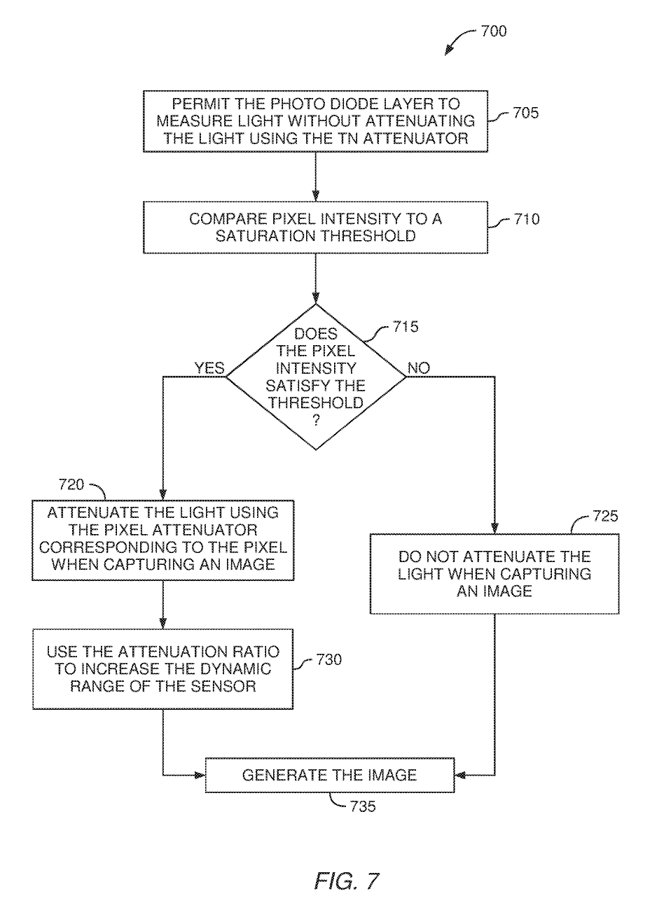

FIG. 7 is a flowchart of a method 700 for increasing the dynamic range of an image sensor using an individually addressable TN attenuator, according to one embodiment described herein. At block 705, the image sensor captures the intensity of each of photodiodes in the pixels in the array. For example, the image sensor may include a structure shown in FIG. 6B where the image sensor is a single sided sensor image that includes individually controlled attenuators the cover each of the pixels. As such, at block 705, the controller may set the voltage across all of the attenuators to permit as much light as possible to pass through unabated to the underlying photodiodes. However, although the examples below discuss using a single sided sensor image that includes the individually controlled attenuators in FIG. 6B, the same technique may also be applied to one or both sides of a double-sided image sensor.

At block 710, the electronic device measures the intensity at each of the pixels to determine if the pixels are saturated. For example, read out circuitry in the electronic device may include an analog to digital converter (ADC) that converts an analog signal generated by the photodiodes in each of the pixels to a digital value. However, the ADC may have limited dynamic range. For example, the ADC may map the analog voltages generated by the pixels to a digital values between 0-1000. However, if the analog voltages map to values that exceed the range of the ADC, then the pixels are saturated—i.e., are limited to the maximum value of the ADC. For example, if the analog voltages outputted by the photodiodes map to digital values that exceed a saturation threshold—i.e., the maximum output of the ADC—the output of the ADC is saturated and outputs only 1000 in response to these analog voltages.

At block 715, the electronic device identifies which of the pixels has photodiodes that output values that saturate the hardware in the read out circuitry (i.e., the ADCs). That is, some of the photodiodes may output voltages that saturate the ADCs while others do not. For example, the photodiode array may be used to capture an image that includes a person standing in front of a brightly lit window. While the photodiodes struck by light reflecting off the person (which is shaded and darker than the window) do not saturate the ADCs, the photodiodes struck by the bright light coming from the window do saturate the ADCs. The electronic device may use a threshold such as the maximum output of the ADC to determine if the photodiode in a pixel is saturated. That is, if the voltage outputted by a photodiode outputs the maximum digital value of the ADC, the electronic device deems that the measurement generated by the photodiode has saturated the ADC. By evaluating the ADC outputs for all the pixels, the electronic device can determine which are saturated and which are not.

If at least one of the pixels is saturated, at block 720, the electronic device uses the individual attenuator corresponding to the saturated pixel to attenuate the light received by the pixel. For example, the electronic device may reduce the attenuator by 50%. However, if a pixel is not saturated, at block 725, the electronic device controls the individual attenuator correspond to the unsaturated pixel to permit the light to pass through unabated—i.e., the attenuator is set in the mode that permits the most light to pass through.

At block 730, the electronic device performs a gain compensation to compensate for the attenuation caused by the individual attenuator on the saturated photodiodes. For example, the electronic device may know that the light was attenuated by 50% before striking the photodiode. As such, if the output of the ADC corresponding to the voltage on the saturated photodiode is 800 (and the ADC has a dynamic range of 0-1000), then the electronic device can double this value to result in a digital value of 1600 for this pixel. Thus, even though the range of the ADC is 0-1000, by attenuating the saturated photodiodes by 50%, the dynamic range can be double. That is, the electronic device can assign digital values (which may each correspond to a unique color) from 0-2000 thereby increasing the dynamic range of the image sensor.

At block 735, the electronic device generates an image using the measurements received by the photodiodes in the pixels. That is, the electronic device processes the measurements from the photodiodes into a digital value for each pixel that indicates the color of the pixel. Later, an electronic display can convert the digital values of the image into analog values that are used to set the color of each pixel in the display.

In one embodiment, the electronic device again checks to see if the photodiodes that were determined to be saturated at block 715 are still saturated even after attenuating the light at block 720. For example, if the voltages provided by the saturated photodiodes still saturate the ADC (e.g., the ADC still outputs its maximum value), the electronic device increases the attenuation of the individual TN attenuators. For example, instead of 50% attenuation, the TN attenuators are set to 75% attenuation. If the voltage outputted by the photodiode is now within the dynamic range of the ADC, the electronic device performs the gain compensation discussed above but instead compensates for the 75% attenuation rather than a 50% attenuation to derive the digital value (and the color) for the pixel. Again, by increasing the attenuation of the TN attenuators, the dynamic range of the read out circuitry can be increased. In one embodiment, using the individually controlled TN attenuators permits an ADC with lower dynamic range to be used to achieve the same overall dynamic range, thereby decreasing the cost of the electronic device.

In the preceding, reference is made to embodiments presented in this disclosure. However, the scope of the present disclosure is not limited to specific described embodiments. Instead, any combination of the features and elements described herein, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

The present invention may be a system, a method, and/or a computer program product. The computer program product may include a computer readable storage medium (or media) having computer readable program instructions thereon for causing a processor to carry out aspects of the present invention.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality and operation of possible implementations of systems, methods and computer program products according to various embodiments. In this regard, each block in the flowchart or block diagrams may represent a module, segment or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

In view of the foregoing, the scope of the present disclosure is determined by the claims that follow.

1. An image sensor, comprising:
a first selectable attenuator;
a second selectable attenuator;
a photodiode layer disposed optically between the first and second selectable attenuators, the photodiode layer comprising an array of photodiodes; and
a controller configured to:
control attenuation factors of the first and second selectable attenuators during a first time period to capture a first image relative to a first side of the array of the photodiodes, and
control the attenuation factors of the first and second selectable attenuators during a second time period to capture a second image relative to a second side different from the first side of the array of the photodiodes.

2. The image sensor of claim 1, wherein, during the first time period, the first selectable attenuator is in a first mode with a low attenuation factor that permits incident light to strike the first side of the array of the photodiodes and the second selectable attenuator is in a second mode with a high attenuation factor that substantially blocks incident light from striking the second side of the array of the photodiodes.

3. The image sensor of claim 2, wherein, during the second time period, the first selectable attenuator is in the second mode and substantially blocks incident light from striking the first side of the array of the photodiodes and the second selectable attenuator is in the first mode that permits incident light to strike the second side of the array of the photodiodes.

4. The image sensor of claim 1, further comprising:
read out circuitry configured to:
process data captured during the first time period to generate the first image of a first view of the image sensor, and
process data captured during the second time period to generate the second image of a second view of the image sensor.

5. The image sensor of claim 4, wherein the first view corresponds to a front side of the image sensor and the second view corresponds to a backside of the image sensor opposite the front side.

6. The image sensor of claim 1, wherein the first and second selectable attenuators each comprise a twisted nematic (TN) structure.

7. The image sensor of claim 6, wherein the TN structure includes a first polarization filter, a second polarization filter, and an alignment layer disposed between the first and second polarization filter, wherein the alignment layer comprise liquid crystal material.

8. The image sensor of claim 1, wherein the first and second selectable attenuators each comprise a mechanical shutter.

9. A method, comprising:
controlling a first attenuation factor of first selectable attenuator in an image sensor during a first time period to capture a first image relative to a first side of an array of photodiodes;
controlling an second attenuation factor of a second selectable attenuator in the image sensor during the first time period to substantially block incident light from striking a second side of the array of photodiodes;
controlling the first attenuation factor the first selectable attenuator during a second time period to substantially block incident light from striking the first side; and
controlling the second attenuation factor of the second selectable attenuator during the second time period to capture a second image relative to the second side of the array of photodiodes.

10. The method of claim 9, wherein, during the first time period, the first selectable attenuator is in a first mode with a low attenuation factor that permits incident light to strike the first side of the array of the photodiodes and the second selectable attenuator is in a second mode with a high attenuation factor that substantially blocks incident light from striking the second side of the array of the photodiodes.

11. The method of claim 10, wherein, during the second time period, the first selectable attenuator is in the second mode and substantially blocks incident light from striking the first side of the array of the photodiodes and the second selectable attenuator is in the first mode that permits incident light to strike the second side of the array of the photodiodes.

12. The method of claim 9, further comprising:
processing data captured during the first time period to generate the first image of a first view of the image sensor; and
processing data captured during the second time period to generate the second image of a second view of the image sensor.

13. The method of claim 12, wherein the first view corresponds to a front side of the image sensor and the second view corresponds to a backside of the image sensor opposite the front side.

14. The method of claim 9, wherein the first and second selectable attenuators each comprise a TN structure.

15. The method of claim 9, wherein the first and second selectable attenuators each comprise a mechanical shutter.

16. An image sensor, comprising:
photodiodes disposed in an array;
a TN attenuator layer comprising a plurality of individually addressable TN attenuators disposed over respective ones of the photodiodes; and
a controller configured to:
receive an intensity measurement for a first photodiode in the array of photodiodes;
upon determining the first photodiode is saturated based on the intensity measurement, adjust a gain of a first TN attenuator of the TN attenuators corresponding to the first photodiode thereby reducing the amount of light striking the first photodiode; and
generate an image using measurements received from the photodiodes.

17. The image sensor of claim 16, wherein adjusting the gain of the first TN attenuator results in a measurement generated by the first photodiode to be within a dynamic range of a hardware circuitry receiving the measurement.

18. The image sensor of claim 17, wherein the controller is configured to, before generating the image, adjust the measurement generated by the first photodiode to compensate for the adjusted gain of the first TN attenuator.

19. The image sensor of claim 16, wherein the controller is configured to:
receive respective intensity measurements for a plurality of the photodiodes, and
upon determining the plurality of photodiodes are saturated based on the respective intensity measurements, adjust gains of a plurality of the TN attenuators corresponding to the plurality of photodiodes thereby reducing the amount of light striking the plurality of photodiodes.

20. The image sensor of claim 16, wherein the controller is configured to:
receive an intensity measurement for a second photodiode in the array of photodiodes; and
upon determining the second photodiode is not saturated based on the intensity measurement, measure a voltage from the second photodiode without reducing the amount of light striking the second photodiode using the TN attenuators, wherein the voltage is used to generate the image.
such, only the light entering at the backside strikes the photodiodes.
